(19) United States
(12) Patent Application Publication
(10) Pub. No.: US 2026/0291435 A1
(43) Pub. Date: Sep. 24, 2026

(54) INDUCTOR-CAPACITOR (LC)-VOLTAGE CONTROLLED OSCILLATOR (VCO) AND METHOD OF OPERATING THE SAME

(71) Applicant: Samsung Electronics Co., Ltd., Suwon-si (KR)

(72) Inventors: Subhadeep Datta, Bengaluru (IN); Arnab Banerjee, Bengaluru (IN); Ayush Tripathi, Bengaluru (IN); Avneesh Singh Verma, Bengaluru (IN); Jeevarathinam Errakutty Ganesan, Bengaluru (IN); Sumanth Chakkirala, Bengaluru (IN); Vishnu Kalyanamahadevi Gopalan Jawarlal, Bengaluru (IN)

(21) Appl. No.: 19/556,421

(22) Filed: Mar. 4, 2026

(30) Foreign Application Priority Data
Mar. 19, 2025 (IN) 202541024783
Jan. 27, 2026 (IN) 202541024783

(51) Int. Cl. H03B 5/04; H03B 5/06; H03B 5/12; H03L 7/099

(52) U.S. Cl. CPC H03B 5/04; H03B 5/06; H03B 5/1228; H03B 2200/0038; H03B 2200/0042; H03B 2200/0058; H03L 7/099

(57) ABSTRACT

An Inductor-Capacitor (LC)-Voltage Controlled Oscillator (VCO) includes a current generation circuit that generates a Proportional To Absolute Temperature (PTAT) current, a varactor bias voltage generation circuit that generates a varactor bias voltage based on the PTAT current and on both a process variation and a temperature variation, an LC tank including a varactor circuit that receives the varactor bias voltage to compensate the process variation and the temperature variation

### CROSS-REFERENCE TO RELATED APPLICATIONS

This application claims priority under 35 U.S.C. § 119 to Indian Provisional Patent Application No. 202541024783, filed with the Office of the Controller General Patents, Designs and Trade Marks in India on Mar. 19, 2025 and Indian Patent Application No. 202541024783, filed with the Office of the Controller General Patents, Designs and Trade Marks in India on Jan. 27, 2026, the entire contents of which are hereby incorporated by reference.

### BACKGROUND

Voltage-Controlled Oscillators (VCOs) are essential components in integrated circuits. The VCOs are especially important in systems that need precise frequency generation. These systems include precision clock generation systems, such as Phase-Locked Loops (PLLs), and other timing-sensitive applications. Among the different types of the VCOs, an Inductor-Capacitor (LC)-VCO is widely used. LC-VCOs are selected for superior phase noise performance. However, one significant limitation of conventional LC-VCOs is their sensitivity to temperature variations, which can adversely impact frequency stability. Moreover, temperature-induced shifts in a resonance frequency can cause jitter, destabilize PLLs, and disrupt communication links, thereby degrading overall system performance.

Further, with the advent of modern System-on-chip (SoC) applications, new challenges arise with LC-VCOs. These challenges are especially prominent in automotive and industrial systems. The conventional LC-VCOs are exposed to wide temperature ranges due to heating in the SoCs. For example, the temperature can range from as low as −45° C. to as high as 125° C. The high temperature variations demand robust temperature compensation solutions that can maintain frequency stability over broad temperature spans. The said issue is particularly significant in automotive and industrial systems, where precise frequency control is required despite substantial temperature fluctuations.

In response to the above-mentioned challenges, several techniques have been developed to address temperature drift in the LC-VCOs. However, conventional techniques to mitigate temperature-induced frequency drift in the LC-VCOs often involve the use of varactors with a negative temperature coefficient. While such solutions can provide some level of compensation, the conventional techniques are inefficient in terms of area consumption and under strict voltage constraints.

Therefore, there exists a strong need to develop an improved LC-VCO while addressing the aforementioned challenges.

### SUMMARY

The present disclosure relates to the field of System-on-Chip (SoC) circuits. Particularly, the present disclosure relates to an Inductor-Capacitor (LC)-Voltage-Controlled Oscillator (VCO).

This summary is provided to introduce a selection of concepts, in a simplified format, that are further described in the detailed description of the present disclosure. This summary is not intended for limiting the scope of the present disclosure.

According to one implementation of the present disclosure, an Inductor-Capacitor (LC)-Voltage Controlled Oscillator (VCO) is disclosed. The LC-VCO comprises a current generation circuit configured to generate a Proportional To Absolute Temperature (PTAT) current based on a feedback mechanism. The LC-VCO further comprises a varactor bias voltage generation circuit connected to the current generation circuit. The varactor bias voltage generation circuit is configured to generate a varactor bias voltage based on the PTAT current. The varactor bias voltage is dependent on a process variation and a temperature variation that are associated with the LC-VCO. The LC-VCO further comprises an LC tank connected to the varactor bias voltage generation circuit. The LC tank comprises a varactor circuit configured to receive the varactor bias voltage to compensate for the process variation and the temperature variation.

According to one implementation of the present disclosure, a method of operating an LC-VCO is disclosed. The method of operating the LC-VCO comprises generating, using a current generation circuit of the LC-VCO, a proportional to absolute temperature (PTAT) current, generating, using a varactor bias voltage generation circuit of the LC-VCO, a varactor bias voltage based on the PTAT current and on both a process condition and a temperature condition that are associated with the LC-VCO, adjusting, using a LC tank of the LC-VCO, an effective gate overdrive voltage of a capacitor of the LC tank based on the varactor bias voltage to compensate for a process variation of the process condition and a temperature variation of the temperature condition.

To further clarify the advantages and features of the present disclosure, a more particular description of the present disclosure will be rendered by reference to specific implementations thereof, which are illustrated in the appended drawings. It is appreciated that these drawings depict only typical implementations of the present disclosure and are therefore not to be considered limiting of its scope. The present disclosure will be described and explained with additional specificity and detail with the accompanying drawings.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIGS. 1 and 2 illustrate a graphical representation of a varactor linearization technique;

FIG. 3 illustrates a circuit diagram of an Inductor-Capacitor (LC)-Voltage Controlled Oscillator (VCO), in accordance with an implementation of the present disclosure;

FIGS. 4A and 4B illustrate an exemplary fabrication technique to fabricate the LC-VCO, in accordance with one or more implementations of the present disclosure;

FIG. 5 illustrates a computing system, in accordance with one or more implementations of the present disclosure; and

FIG. 6 illustrates a method of operating the LC-VCO, in accordance with one or more implementations of the present disclosure.

Further, skilled artisans will appreciate that elements in the drawings are illustrated for simplicity and may not have necessarily been drawn to scale. For example, the flow charts illustrate the method in terms of the most prominent steps involved to help to improve understanding of aspects of the present disclosure. Furthermore, in terms of the construction of the circuit, one or more components of the circuit may have been represented in the drawings by conventional symbols, and the drawings may show only those specific details that are pertinent to understanding the implementations of the present disclosure so as not to obscure the drawings with details that will be readily apparent to those of ordinary skill in the art having the benefit of the description herein.

### DETAILED DESCRIPTION

For the purpose of promoting an understanding of the principles of the present disclosure, reference will now be made to the implementation illustrated in the drawings and specific language will be used to describe the same. It will nevertheless be understood that no limitation of the scope of the present disclosure is thereby intended, such alterations and further modifications in the illustrated system, and such further applications of the principles of the present disclosure as illustrated therein being contemplated as would normally occur to one skilled in the art to which the present disclosure relates.

It will be understood by those skilled in the art that the foregoing general description and the following detailed description are explanatory of the present disclosure and are not intended to be restrictive thereof.

Reference throughout this specification to “an aspect”, “another aspect” or similar language means that a particular feature, structure, or characteristic described in connection with the implementation is included in at least one implementation of the present disclosure. Thus, appearances of the phrase “in an implementation”, “in another implementation” and similar language throughout this specification may, but do not necessarily, all refer to the same implementation.

The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more systems or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components.

Whether or not a certain feature or element was described in singular form, it may still be referred to as “one or more features” or “one or more elements” or “at least one feature” or “at least one element.” Furthermore, the use of the terms “one or more” or “at least one” feature or element does not preclude there being none of that feature or element unless otherwise specified by limiting language such as “there needs to be one or more . . . ” or “one or more element is required.”

Unless otherwise defined, all terms, and especially any technical and/or scientific terms, used herein may be taken to have the same meaning as commonly understood by one having ordinary skill in the art.

Example implementations of the present disclosures will be described below in detail with reference to the accompanying drawings.

As modern System-on-Chip (SoC) solutions evolve, there is a growing demand for higher computational power and faster data rates, particularly in mobile applications and timing controllers used in Ultra High Definition (UHD)-Television (TV) applications. In the context of mass production of semiconductor circuits, such as on the order of one million units, the devices exhibit variability in certain characteristics, such as threshold voltage, gate capacitance, mobility, and the like, due to inherent statistical variations in the manufacturing process. As a result, among a production batch of one million units, certain devices exhibit higher MOSFET threshold voltages, leading to slower device performance, hereinafter referred to as “slow corners.” Conversely, a subset of devices exhibits lower-than-expected MOSFET threshold voltages, leading to faster device performance, hereinafter referred to as “fast corners.” The distribution of these variations typically conforms to a random Gaussian distribution. The “slow corner” corresponds to one end of the distribution, the “fast corner” corresponds to the opposite end, and the central or nominal value of the distribution (e.g., a target threshold voltage value) is referred to as the “typical corner.” “fast corner” and “slow corner” can be based on manufacturing process conditions and process variations and associated with a deviation of a threshold voltage value of a transistor from the target threshold voltage value.

Further, the SoC environment is prone to significant temperature drift, sometimes exceeding 60° C. Automotive systems, in particular, require even wider temperature drift tolerance. As semiconductor technology continues to progress according to Moore's Law, with a focus on smaller process nodes and lower supply voltages, the demand for high-performance analog circuits like LC-VCOs is becoming increasingly important. These circuits must be capable of functioning under ultra-low voltages while simultaneously managing substantial temperature drift, especially in applications where reliable clocking is essential for system stability and performance. However, one significant limitation of LC-VCOs is their sensitivity to temperature variations, which can adversely impact frequency stability. Temperature-induced shifts in the resonance frequency can cause jitter, destabilize PLLs, and disrupt communication links, thereby degrading overall system performance.

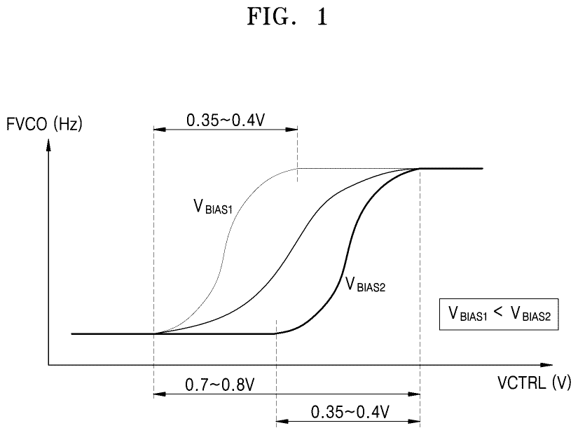

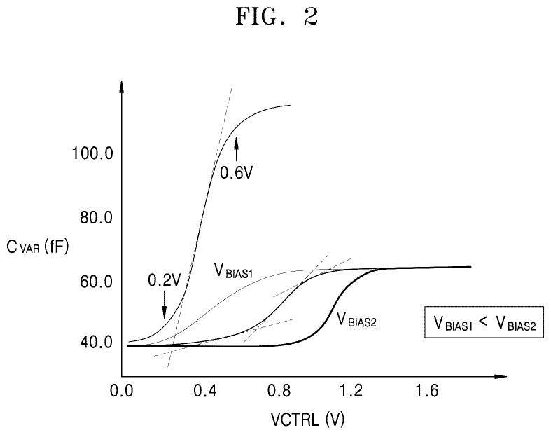

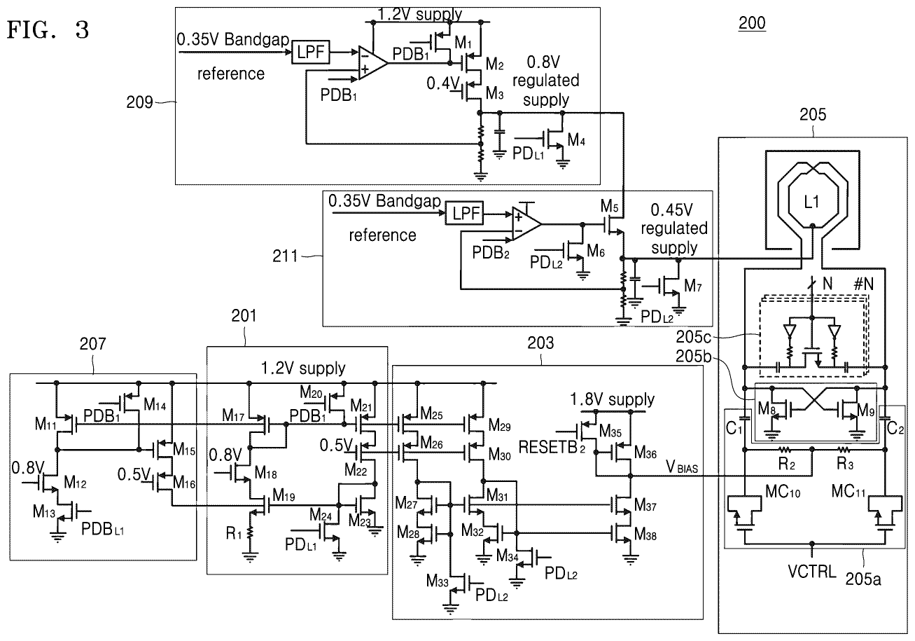

FIGS. 1 and 2 illustrate a graphical representation of a varactor linearization technique. Varactor bias linearization is one such method commonly used to mitigate temperature-induced frequency variations in the LC-VCOs. However, said technique has limited efficacy in ultra-low voltage applications, as shown in FIGS. 1 and 2. As shown in FIGS. 1 and 2, the varactor linearization technique for wide tuning is not suitable for thick-oxide device-less (e.g., without using thick-oxide devices), and ultra-low voltage applications. FIG. 1 explains a varactor linearization scheme where the varactor is broken into several parts and instead of giving a common bias voltage to all of the parts of the varactors, different bias voltages V_{BIAS1} and V_{BIAS2} from low to high are used to bias the different parts of the varactor. Varactor threshold voltage in thin-oxide devices follows a Complementary to Absolute Temperature (CTAT) profile. Accordingly, the tuning capability of the varactor heavily comes down in the slow process and low temperature corner combination. Hence, a lower bias voltage V_{BIAS1} can help restore the varactor gain and hence, its fine-tuning capability in this condition. Similarly, the varactor threshold comes down in the fast process and high temperature corner combination, increasing the varactor gain and making PLL noisier and jittery. A higher bias voltage V_{BIAS2} can help counter this increased gain in the fast process and higher temperature corner combination. Therefore, overall, using a gradient of bias voltages V_{BIAS1} and V_{BIAS2} for portions of the varactor can help mitigate the effect of process and temperature variation on LC-VCOs by linearizing the varactor gain over a broader range of PLL control voltages. However, the downside of this technique is explained in FIG. 3. As shown, the varactor linearization technique requires a much wider voltage range for the varactor to be useful and proves to be ineffective in cases where the LC-VCO is to be designed in a lower technology node, powered by ultra-low voltage.

Accordingly, the present disclosure provides an Inductor-Capacitor (LC)-Voltage-Controlled Oscillator (VCO) suitable for thick-oxide device-less, and ultra-low voltage applications.

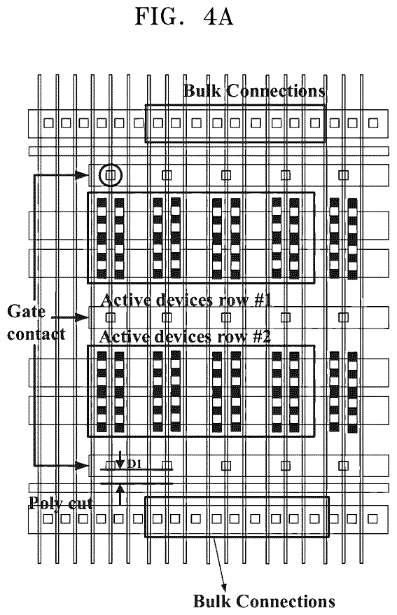

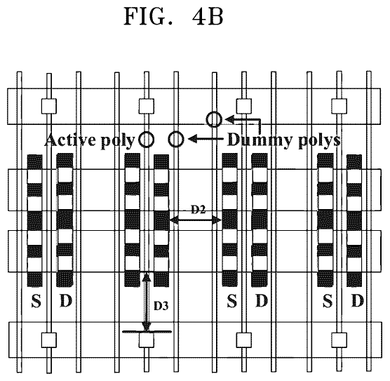

FIG. 3 illustrates a circuit diagram of an Inductor-Capacitor (LC)-Voltage Controlled Oscillator (VCO) 200, in accordance with an implementation of the present disclosure. FIGS. 4A and 4B illustrate an exemplary fabrication technique to fabricate the LC-VCO 200, in accordance with one or more implementations of the present disclosure. In an implementation, the disclosed LC-VCO 200 may be a part of a Phase Locked Loop (PLL).

As shown in FIG. 3, the LC-VCO 200 may include a current generation circuit 201, a varactor bias voltage generation circuit 203, an LC tank 205, a start-up circuit 207, a first voltage regulator circuit 209 and a second voltage regulator circuit 211. The current generation circuit 201 connected to the varactor bias voltage generation circuit 203. The current generation circuit 201 is configured to generate a Proportional To Absolute Temperature (PTAT) current. The current generation circuit 201 may comprise a first set of P-channel Metal-Oxide Semiconductor (PMOS) transistors M₁₇ and M₂₁ connected in a current mirror configuration and a first set of N-channel MOS (NMOS) transistors M₁₉ and M₂₃ connected in the current mirror configuration. In an implementation, the first set of PMOS transistors M₁₇ and M₂₁ and the first set of NMOS transistors M₁₉ and M₂₃ are thin-oxide transistors. Further, the current generation circuit 201 may comprise one or more protection transistors. For example, the current generation circuit 201 may include protection transistors M₁₈ and M₂₂. For example, the protection transistor M₁₈ is implemented with NMOS transistor and the protection transistor M₂₂ is implemented with PMOS transistor. The protection transistors M₁₈ and M₂₂ are used to ensure the reliability of the current generation circuit 201 for thin-oxide transistors operating with more than 1 voltage [V] supply. The reliability limit of thin-gate N-type transistor and/or P-type transistor is under 1V. The at least one of protection transistors M₁₈ and M₂₂ serves as a protection device powered by constant bias voltages from a power supply of more than 1V. During power-down, low-impedance nodes are set to the power supply and/or ground (GND) by pull-up switches and/or pull-down switches, potentially causing fatal voltage over-stress in single P-type transistor and/or N-type transistor with common terminals to these nodes. The protection transistors M₁₈ and M₂₂ mitigate this risk by sharing the over-stress voltage between at least two thin-oxide transistors, such as the first set of PMOS transistors M₁₇ and M₂₁ and the first set of NMOS transistors M₁₉ and M₂₃. For example, a drain terminal of the protection transistor M₁₈ is connected to a gate terminal and the drain terminal of the PMOS transistor M₁₇. The gate terminal of the protection transistor M₁₈ is connected to a power supply of 0.8V. Alternatively, the gate terminal of the protection transistor M₁₈ may be connected to any other suitable power supply as required for the application of LC-VCO 200. Similarly, a source terminal of the protection transistor M₂₂ is connected to the drain terminal of the PMOS transistor M₂₁. The gate terminal of the protection transistor M₂₂ is connected to a power supply of 0.5V. Alternatively, the gate terminal of the protection transistor M₂₂ may be connected to any other suitable power supply as required for the application of LC-VCO 200. Similarly, the source terminal of the protection transistor M₁₈ is connected to the drain terminal of the NMOS transistor M₁₉. The drain terminal of the protection transistor M₂₂ is connected to the gate terminal and the drain terminal of the NMOS transistor M₂₃. Further, as shown, the source terminals of the first set of PMOS transistors M₁₇ and M₂₁ are connected to a power supply of 1.2V. Alternatively, the source terminals of the first set of PMOS transistors M₁₇ and M₂₁ may be connected to any other suitable power supply as required for the application of LC-VCO 200. The gate terminals of the first set of PMOS transistors M₁₇ and M₂₁ are connected with each other. The source terminals of the first set of NMOS transistors M₁₉ and M₂₃ are connected to GND. Further, the source terminal of the NMOS transistor M₁₉ is connected to the GND through a resistor R₁. The gate terminals of the first set of NMOS transistors M₁₉ and M₂₃ with each other. A first Power Down (PD) signal PD_{L1} is applied to a gate terminal of a NMOS transistor M_{24.} A source terminal of the NMOS transistor M₂₄ is connected to the GND and a drain terminal of the NMOS transistor M₂₄ is connected to the gate terminals of the NMOS transistors M₁₉ and M₂₃. In an implementation, the current generation circuit 201 may be configured to generate the PTAT current based on a feedback mechanism. In particular, the slightest disturbance in any of the bias nodes of the transistors M₁₇ to M₂₃ gets amplified by a positive feedback mechanism present in the current generation circuit 201. The positive feedback mechanism is generated when the bias current is repeatedly mirrored by two current mirrors, i.e., PMOS mirrors to NMOS mirrors to PMOS mirrors to NMOS mirrors, and so on. Accordingly, the current generation circuit 201 may generate the PTAT current. Further, in an implementation, the size ratio of the PMOS transistors M₁₇ and M₂₁ is 1:1, whereas the size ratio of the NMOS transistors M₁₉ and M₂₃ is K:1. For example, the size ratio is referred to an aspect ratio and/or a Width/Length ratio (W/L ratio). The value of K and the resistor R₁ together decide the biasing point of the current generation circuit 201.

Further, the LC-VCO 200 may comprise a start-up circuit 207 connected to the current generation circuit 201. The start-up circuit 207 may be configured to protect (e.g., restrict) the current generation circuit 201 from generating the PTAT current of a zero value. For example, the start-up circuit 207 may be configured to ensure that the current generation circuit 201 does not remain in a non-functional state where no PTAT current is produced. The start-up circuit 207 may comprise a plurality of PMOS transistors M₁₁, M₁₄, and M₁₅ and at least one NMOS transistor. The start-up circuit 207 may include a NMOS transistor M₁₃. The start-up circuit 207 may further comprise one or more protection transistors. For example, the start-up circuit 207 may include protection transistors M₁₂ and M₁₆. For example, the protection transistor M₁₂ is implemented with NMOS transistor and the protection transistor M₁₆ is implemented with PMOS transistor. The source terminals of the PMOS transistors M₁₁, M_{14,} and M₁₅ are connected to the power supply of 1.2V. Alternatively, the source terminals of the PMOS transistors M₁₁, M_{14,} and M₁₅ may be connected to any other suitable power supply as required for the application of LC-VCO 200. The drain terminals of the PMOS transistors M₁₁ and M₁₄ are connected to the gate terminal of the PMOS transistor M₁₅. A first Power Down Bar (PDB) signal PDB₁ is applied to the gate terminal of the PMOS transistor M₁₄. A PDB signal goes from ground to supply when a corresponding transistor, such as the PMOS transistor M₁₄ is brought from a powered down state to an active state. The gate terminal of the PMOS transistor M₁₁ is connected to the gate terminal of the PMOS transistor M₁₇. The drain terminal of the PMOS transistor M₁₁ is connected to the drain terminal of the protection transistor M₁₂. The gate terminal of the protection transistor M₁₂ is connected to a power supply of 0.8V. Alternatively, the gate terminal of the protection transistor M₁₂ may be connected to any other suitable power supply as required for the application of LC-VCO 200. The source terminal of the protection transistor M₁₂ is connected to the drain terminal of the NMOS transistor M₁₃. The source terminal of the NMOS transistor M₁₃ is connected to GND. A first signal PDB_{L1} is applied to the gate terminal of the NMOS transistor M₁₃ as a power supply. The drain terminal of the PMOS transistor M₁₅ is connected to the source terminal of the protection transistor M₁₆. The gate terminal of the protection transistor M₁₆ is connected to the power supply of 0.5V. Alternatively, the gate terminal of the protection transistor M₁₆ may be connected to any other suitable power supply as required for the application of LC-VCO 200. The drain terminal of the protection transistor M₁₆ is connected to the gate terminal of the NMOS transistor M₁₉. Further, it should be noted that the PMOS transistors M₁, M₁₄, M_{20,} and M₃₅ are power-down pull-up transistors used to pull-up the respective node voltages to supply in powered down conditions. Similarly, the NMOS transistors M₄, M₆, M₇, M₂₄, M_{33,} and M₃₄ are the power-down pull-down transistors used to pull-down the respective node voltages to ground in powered down condition.

The generated PTAT current is forwarded to the varactor bias voltage generation circuit 203 that is connected to the LC tank 205. The varactor bias voltage generation circuit 203 may be configured to generate a varactor bias voltage (V_{BIAS}) based on the PTAT current. In particular, the transistors M₂₅ to M₃₈ constitute the varactor bias voltage generation circuit 203. The PMOS transistor M₂₉ mirrors the PTAT current (where the protection transistor M₃₀ acts as a cascode (cascade and triode) transistor) and biases the NMOS transistor M₃₂ diode to generate bias voltage for a current source transistor (For example, a NMOS transistor M₃₈). The PMOS transistor M₂₅ mirrors the PTAT current (where the protection transistor M₂₆ acts as the cascode transistor) and biases the NMOS transistors M₂₇ and M₂₈ diode to generate bias for the NMOS transistor M₃₇ that acts as the cascode transistor. The mirrored current in the final branch of NMOS transistors M₃₇ and M₃₈ is then sinked from the PMOS transistor M₃₆ diode to generate the varactor bias voltage (V_{BIAS}) for the LC-VCO 200. In an implementation, the varactor bias voltage (V_{BIAS}) is dependent on a process variation and a temperature variation associated with the LC-VCO 200. The varactor bias voltage generation circuit 203 may comprise a plurality of transistors M₂₅, M₂₇, M₂₈, M₂₉, M₃₁, M₃₂, M₃₃, M₃₄, M₃₅, M₃₆, M₃₇, and M₃₈ configured to mirror the PTAT current. For example, The varactor bias voltage generation circuit 203 may comprise a second set of PMOS transistors M₂₅, M₂₉, M₃₅, and M₃₆ and a second set of NMOS transistors M₂₇, M₂₈, M₃₁, M₃₂, M₃₇, and M₃₈. The varactor bias voltage generation circuit 203 may further comprise one or more protection transistors. For example, M₂₆ and M₃₀. For example, the varactor bias voltage generation circuit 203 may include the protection transistors M₂₆ and M₃₀ that are implemented with PMOS transistors. The source terminals of the PMOS transistors M₂₅ and M₂₉ are connected to a power supply of 1.2V. Alternatively, the source terminals of the PMOS transistors M₂₅, and M₂₉ may be connected to any other suitable power supply as required for the application of LC-VCO 200. The gate terminals of the PMOS transistors M₂₅ and M₂₉ are connected with each other. The drain terminals of the transistors M₂₅ and M₂₉ are connected to the source terminals of the transistors M₂₆ and M₃₀, respectively. The gate terminals of the protection transistors M₂₆ and M₃₀ are connected with each other. The drain terminals of the protection transistors M₂₆ and M₃₀ are connected to the drain terminals of the NMOS transistors M₂₇ and M₃₁, respectively. The gate terminals of the NMOS transistors M₂₇ and M₃₁ are connected to each other. The source terminals of the NMOS transistors M₂₇ and M₃₁ are connected to the drain terminals of the NMOS transistors M₂₈ and M₃₂, respectively. The source terminals of the NMOS transistors M₂₈, M₃₂, M₃₃, and M₃₄ are connected to the GND. The gate terminal of NMOS transistor M₂₈ is connected to the drain terminal of the NMOS transistor M₃₃, and the gate terminal and drain terminal of the NMOS transistor M₂₇. A second PD signal PD_{L2} is applied to the gate terminal of the NMOS transistor M₃₃. The gate terminals of the NMOS transistors M₃₁ and M₃₇ are connected with each other. The source terminal of the NMOS transistor M₃₁ is connected to the drain terminal of the NMOS transistor M₃₂. The gate terminals of the NMOS transistors M₃₂ and M₃₈ are connected with each other. The drain terminal of the NMOS transistor M₃₄ is connected to the gate terminals of the NMOS transistors M₃₂ and M₃₈ and the drain terminals of the protection transistor M₃₀ and the NMOS transistor M₃₁. The second PD signal PD_{L2} is applied to the gate terminal of the NMOS transistor M₃₄. Further, the source terminals of the PMOS transistors M₃₅ and M₃₆ are connected to a power supply of 1.8V. Alternatively, the source terminals of the PMOS transistors M₃₅ and M₃₆ may be connected to any other suitable power supply as required for the application of LC-VCO 200. The gate terminal of the PMOS transistor M₃₅ is connected to a reset signal RESETB₂. The reset signal RESETB₂ is corresponded to the second PDB signal PDB₂. The drain terminal of the PMOS transistor M₃₅ is connected to the drain terminal and the gate terminal of the PMOS transistor M₃₆. The drain terminal of the PMOS transistor M₃₆ is connected to the drain terminal of the NMOS transistor M₃₇. The gate terminal of the NMOS transistor M₃₇ is connected to the gate terminal of the NMOS transistor M₃₁. The source terminal of the NMOS transistor M₃₇ is connected to the drain terminal of the NMOS transistor M₃₈. The gate terminal of the NMOS transistor M₃₈ is connected to the gate terminal of the NMOS transistor M₃₂.

At least one of the plurality of transistors M₂₅, M₂₇, M₂₈, M₂₉, M₃₁, M₃₂, M₃₃, M₃₄, M₃₅, M₃₆, M₃₇, and M₃₈ is configured to mirror the PTAT current. In an implementation, the PMOS transistor M₂₉ mirrors the PTAT current and biases the NMOS transistor M₃₈ to generate bias for a current source transistor (e.g. M₃₈). Further, the PMOS transistors M₂₅ and M₂₆ mirror the PTAT current and bias one or more NMOS transistors M₂₇ and M₂₈. The one or more NMOS transistors M₂₇ and M₂₈ then generate a bias for a cascode transistor (e.g. M₃₇). The mirrored PTAT current has two levels of process and temperature tracking. In the first level of the process and temperature tracking, the Bias current may be generated using the below equation:

$$I\_BIAS = ( 1 / {R}^{2} ) ( 1 / {uC}_{ox} ) {( 1 - 1 / √ ( N ) )}^{2 ,} \qquad ( 1 )$$

Where I_BIAS is a valid solution for the varactor bias voltage generation circuit 203. R is the resistor used, i.e., R₁, u (mu) is the mobility of the thin-gate transistors, Cₒₓ is its gate-oxide capacitance, N is the mirror ratio used for the NMOS transistors M₁₉ and M₂₃ current mirror pair.

In fast process corners, the mobility of the transistor is higher which translates to a lower bias sink drawn from a bias PMOS transistor (e.g., M₃₆). The lower bias sink leads to higher varactor bias voltage in fast process corners. Mobility almost does not change with temperature for thin-gate transistors in lower technology nodes. However, the resistor R₁ changes in the PTAT current. The change in resistance (R) translates to the lowest bias sink current in the fast process and high temperature corner combination, which in turn leads to the highest varactor bias voltage. Similarly, in slow process and lower temperature corner combination, a combination of lower mobility and lower resistance leads to the highest current sink from the bias PMOS transistor (e.g., M₃₆) and finally leads to the least varactor bias voltage for the said process and temperature corner combination. Further, the 2^{nd} level of process and temperature tracking is captured in the functioning of the bias PMOS transistor. The output voltage of the bias PMOS transistor is the varactor bias voltage (V_{BIAS}). A threshold voltage of the bias PMOS transistor has a Complementary to Absolute Temperature (CTAT) voltage with a temperature of the LC-VCO 200. Accordingly, the threshold voltage of the bias PMOS transistor becomes the least in the fast process and high temperature corner combination, leading to the generation of an elevated varactor bias voltage. In the slow process and low temperature corner combination, the threshold voltage of the bias PMOS transistor becomes the highest, leading to the generation of a lowered varactor bias voltage. The generated varactor bias voltage (V_{BIAS}) is then forwarded to the LC tank 205. In particular, the varactor threshold voltage in thin-oxide devices follows a CTAT profile. As a result, the varactor's tuning capability is significantly reduced in the slow process and low temperature corner combination. When the bias voltage is lowest under the slow process and low temperature corner combination, it helps restore the varactor's gain and fine-tuning capability. Conversely, in the fast processes and high temperature corner combination, the varactor threshold decreases, which increases the varactor gain and causes the PLL to become noisier and more jittery. By applying the highest bias voltage under the fast processes and high temperature corner combination, the increased gain from the fast process and higher temperature can be mitigated. Accordingly, biasing the varactor with the generated voltage helps neutralize the effects of process and temperature variations on LC-VCOs.

The LC tank 205 may comprise a varactor circuit 205a, a negative transconductance circuit 205b, a resistor circuit 205c, and an inductor L1. The varactor circuit 205a may comprise a second set of thin oxide N-type MOS capacitors (e.g., MC₁₀ and MC₁₁₎, at least two resistors (e.g., R₂ and R₃), and at least two capacitors (e.g., C₁ and C₂). The varactor circuit 205a may configured to receive the varactor bias voltage (V_{BIAS}) to compensate for the process variation and the temperature variation in the LC-VCO 200. An effective gate overdrive voltage of the second set of thin oxide NMOS capacitors MC₁₀ and MC₁₁ is based on the varactor bias voltage (V_{BIAS}). It should be noted that the varactor circuit 205a may be used for continuous, fine-tuning of the frequency of the LC-VCO 200. Depending on the gate overdrive received by the varactor circuit 205a, the capacitance of the varactor circuit 205a changes monotonously which culminates into fine-tuning of the resonant frequency of the LC-VCO 200. In particular, the gate-to-source bias voltage (V_{GS}) of the second set of thin oxide NMOS capacitors MC₁₀ and MC₁₁ may be defined as:

$${V}_{GS} = {V}_{CTRL} - {V}_{BIAS} , \qquad ( 2 )$$

where V_{CTRL} is the control voltage of the PLL
The effective gate overdrive voltage (V_{GO}) of the second set of thin oxide NMOS capacitors MC₁₀ and MC₁₁ may be defined as:

$${V}_{GO} = {V}_{CTRL} - {V}_{BIAS} - {V}_{th} , \qquad ( 3 )$$

where Vₜₕ is the threshold voltage of the second set of thin oxide NMOS capacitors MC₁₀ and MC₁₁.

Accordingly, in an implementation, the temperature variation achieves a higher tuning range across process and temperature variation by tracking the variation of Vₜₕ and cancelling the varactor threshold voltage (Vₜₕ) with the varactor bias voltage (V_{BIAS}). In particular, as known, the Vₜₕ in thin-oxide devices follows the CTAT profile. Accordingly, the tuning capability of the LC-VCO 200 heavily comes down in the slow process and low temperature corner combination. Similarly, the varactor threshold comes down in the fast process and high temperature corner combination, increasing the varactor gain and making PLL noisier and jittery. However, the disclosed techniques track the variation of Vₜₕ and cancel the Vₜₕ with the V_{BIAS}. Thereby, the disclosed techniques neutralise the effect of process and temperature variation on the LC-VCO 200.

Further, in an implementation, the varactor circuit 205a may be designed using one of a dummy poly insertion technique and a varying diffusion spacing technique, as shown in FIGS. 4A and 4B. As shown in FIGS. 4A and 4B, a first distance D1 between gate contact via and poly cut is minimized. Similarly, a second distance D2 between the source and drain is increased by inserting dummy polys. Further, a third distance D3 between gate contact via and oxide diffusion is reduced or minimized. Further, dummy poly insertion spaces the source and drain terminals of a transistor and helps in reducing the parasitic loading between them. Then, reducing or minimizing the first distance D1 and the third distance D3 helps to reduce the gate contact resistance which helps compensate for the loss of the LC tank 205.

Further, the negative transconductance circuit 205b may comprise two NMOS transistors M₈ and M₉. In an implementation, the negative transconductance circuit 205b may compensate for the losses in the LC tank 205. A high fixed parasitic loading from the NMOS transistors M₈ and M₉ loads the LC tank 205, which is detrimental to its tuning range. In an implementation, a combination of the dummy poly insertion technique and a varying diffusion spacing technique has been used to optimize the fixed parasitic loading from the NMOS transistors M₈ and M₉ for a given loss compensation. In some implementations, a dummy gate structure may be positioned between the NMOS transistors M₈ and M₉. Accordingly, the parasitic capacitance contribution from the NMOS transistors M₈ and M₉ is reduced. The reduction in parasitic capacitance contribution allows for an increase in the size of the second set of thin oxide NMOS capacitors MC₁₀ and MC₁₁, leading to a higher tuning range. It should be noted that the structure and working of the resistor circuit 205c, and the inductor L1 are similar to a LC tank known to a person skilled in the art. Hence, the same has not been explained for the sake of brevity of the disclosure.

In an implementation, the LC-VCO 200 may further comprise a first voltage regulator circuit 209 and a second voltage regulator circuit 211. The first voltage regulator circuit 209 and the second voltage regulator circuit 211 may be connected in a cascade configuration to protect the LC-VCO 200 from extremely noisy supplies present in the SoC environment. In an implementation, a single regulator can also be used if the power supply is less noisy. Further, at least one of the first voltage regulator circuit 209 and the second voltage regulator circuit 211 may comprise at least one protection transistor M₃. The output of the second voltage regulator circuit 211 is provided to the inductor L1 for powering the LC-VCO 200. It should be noted that the structure and working of the first voltage regulator circuit 209 and the second voltage regulator circuit 211 are similar to a voltage regulator circuit known to a person skilled in the art. Hence, the same has not been explained for the sake of brevity of the disclosure.

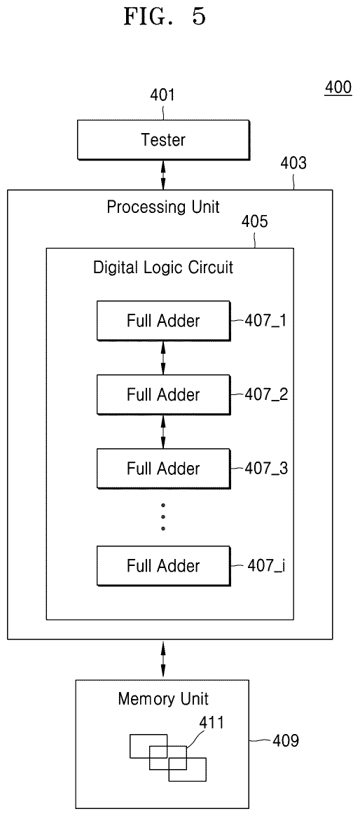

FIG. 5 illustrates a computing system 400, in accordance with one or more implementations of the present disclosure. Referring now to FIG. 5, a computing system 400 is illustrated, in accordance with some example implementations of the present disclosure. The LC-VCO 200 may be implemented in the computing system 400, according to some example implementations of the present disclosure. The computing system 400 is or is incorporated into, but not limited to, a smartphone, a personal digital assistant, a personal computer, smartwatches, fitness trackers, a palmtop computer, a laptop computer, a desktop computer, a communications device, a wireless telephone, a land-line telephone, a web appliance, a network router, switch or bridge, or any other machine capable of executing a set of instructions (sequential or otherwise) that specify actions to be taken by that machine or any other type of electronic system. Further, while a single computing system 400 is illustrated, the term “system” shall also be taken to include any collection of systems or sub-systems that individually or jointly execute a set, or multiple sets, of instructions to perform one or more computer functions.

In some example implementations, the computing system 400 comprises a tester 401, a mega cell, or a system-on-chip (SoC) which includes control logic such as a processing unit 403 (Central Processing Unit), a digital logic circuit 405 including a plurality of full adders 407_1 through 407_i, and/or a memory unit 409 (e.g., Random Access Memory (RAM). The value of “I” is any one of integer numbers greater than 1.

The processing unit 403 can be, for example, a Complex Instruction Set Computer (CISC)-type Central Processing Unit (CPU), a Reduced Instruction Set Computer (RISC)-type CPU, a Digital Signal Processor (DSP), or a Graphics Processing Unit (GPU). The processing unit 403 may be a component in a variety of systems. For example, the processing unit 403 may be part of a standard personal computer or a workstation. The processing unit 403 may be one or more general processors, digital signal processors, application-specific integrated circuits, field-programmable gate arrays, servers, networks, digital circuits, analog circuits, combinations thereof, or other now-known or later-developed devices for analyzing and processing data. The processing unit 403 may implement a software program, such as code generated manually (e.g., programmed).

The memory unit 409 (which can be memory such as RAM, flash memory, or disk storage) stores one or more software applications 411 (e.g., embedded applications) that, when executed by the processing unit 403, perform any suitable function associated with the computing system 400. The memory unit 409 may include but is not limited to computer-readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media and the like.

The tester 401 comprises logic that supports testing and debugging of the computing system 400 executing the software applications 411. For example, the tester 401 can be used to emulate a defective or unavailable component(s) of the computing system 400 to allow verification of how the component(s), that were present on the computing system 400 would perform in various situations (e.g., how the component(s) would interact with the software applications 411). In this way, the software applications 411 can be debugged in an environment that resembles a post-production operation.

The digital logic circuit 405 is used during the execution of the software applications 411. At least one full adder of the plurality of full adders (407_1 through 407_i) includes, or is similar to, the full adder circuitry shown in FIGS. 1-5 in connection and operation.

Accordingly, the present disclosure provides various advantages. For example, in an implementation, in lower technology nodes where thick-gate devices are not present and where the high-performance circuits and systems are powered with ultra-low voltages, the frequency of the disclosed LC-VCO 200 may vary by ±2% as the temperature drifts from −45° C. to 125° C. and vice versa. Further, after the calibration of the disclosed LC-VCO 200 is completed in a PLL, any changes in the frequency must be managed solely by adjustments in the control voltage (V_{CTRL}). Further, the V_{CTRL} movement to counteract the temperature drift falls within the 0.35V V_{CTRL} range. Therefore, the disclosed LC-VCO 200 with a ±4% fine-tuning range comfortably handles a Dynamic Temperature Range (DTR) of −45° C. to 125° C. and vice versa. Further, the disclosed fabrication techniques improved the parasitic of the LC tank 205 and resulted in a 25% parasitic reduction from the cross-coupled pair.

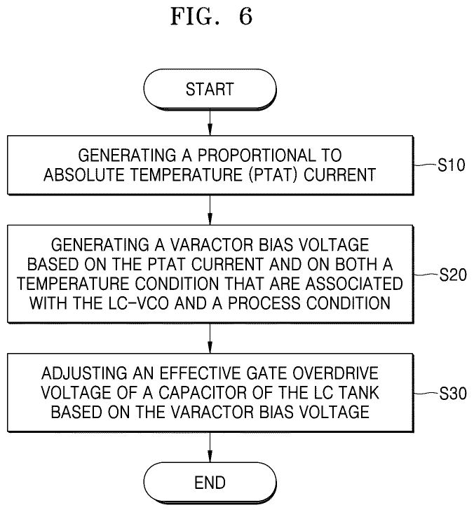

FIG. 6 illustrates a method of operating the LC-VCO 200, in accordance with one or more implementations of the present disclosure. The method of operating the LC-VCO 200 includes steps S10, S20, and S30. In step S10, the current generation circuit 201 of the LC-VCO 200 may generate the PTAT current. In step S20, the varactor bias voltage generation circuit 203 of the LC-VCO 200 may generate the varactor bias voltage based on the PTAT current and on both a process condition and a temperature condition that are associated with the LC-VCO. In step S30, the LC tank 205 of the LC-VCO 200 may adjust the effective gate overdrive voltage of the capacitor (e.g., C₁ and C₂) of the LC tank 205 based on the varactor bias voltage to compensate for a process variation of the process condition and a temperature variation of the temperature.

In an implementation, the method of operating the LC-VCO 200 further includes a step that the start-up circuit 207 of the LC-VCO 200 may restrict the current generation circuit 201 from generating the PTAT current of a zero value.

In an implementation, the method of operating the LC-VCO 200 further includes a step that a first transistor of the varactor bias voltage generation circuit 203 may generate a first bias voltage for a current source transistor of the varactor bias voltage generation circuit 203. And, the method of operating the LC-VCO 200 further includes a step that one or more second transistors of the varactor bias voltage generation circuit 203 may generate a second bias voltage for a cascode transistor of the varactor bias voltage generation circuit 203.

In an implementation, the step S20 comprises generating, using a bias transistor of the varactor bias voltage generation circuit 203, the varactor bias voltage. the bias transistor, the cascode transistor, and the current source transistor are connected in series between a power supply and a ground level.

In the foregoing discussion, the term “connected” means at least either a direct electrical connection between the devices connected or an indirect connection through one or more passive intermediary devices. The term “circuit” means at least either a single component or a multiplicity of passive components, that are connected together to provide a desired function. Also, the terms “coupled to” or “couples with” (and the like) are intended to describe either an indirect or direct electrical connection. Thus, as an example, if an electronic device is coupled to another electronic device, that connection can be through a direct electrical connection, or through an indirect electrical connection via other devices and connections.

While specific language has been used to describe the disclosure, any limitations arising on account of the same are not intended. As would be apparent to a person in the art, various working modifications may be made to implement the present disclosures as taught herein.

The drawings and the forgoing description give examples of example implementations. Those skilled in the art will appreciate that one or more of the described elements may be combined into a single functional element. Alternatively, certain elements may be split into multiple functional elements. Elements from one example implementation may be added to another example implementation.

Also, those acts that are not dependent on other acts may be performed in parallel with the other acts. The scope of example implementations is by no means limited by these specific examples. Numerous variations, whether explicitly given in the specification or not, such as differences in structure, dimension, and use of material, are possible. The scope of example implementations is at least as broad as given by the following claims.

One or more of the elements disclosed above may include or be implemented in one or more processing circuitries such as hardware including logic circuits; a hardware/software combination such as a processor executing software; or a combination thereof. For example, the processing circuitries more specifically may include but are not limited to, a CPU, an Arithmetic Logic Unit (ALU), a Digital Signal Processor, a microcomputer, a Field Programmable Gate Array (FPGA), a System-on-Chip (SoC), a programmable logic unit, a microprocessor, an Application-Specific Integrated Circuit (ASIC), etc.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An inductor-capacitor (LC)-voltage controlled oscillator (VCO) comprising:
a current generation circuit configured to generate a proportional to absolute temperature (PTAT) current;
a varactor bias voltage generation circuit configured to generate a varactor bias voltage based on the PTAT current and on both a process condition and a temperature condition that are associated with the LC-VCO; and
an LC tank comprising a varactor circuit configured to receive the varactor bias voltage to compensate for a process variation of the process condition and a temperature variation of the temperature condition.

2. The LC-VCO of claim 1, further comprising:
a start-up circuit configured to restrict the current generation circuit from generating the PTAT current of a zero value.

3. The LC-VCO of claim 1, wherein the current generation circuit comprises a first set of P-channel Metal-Oxide Semiconductor (PMOS) transistors connected in a mirror configuration and a first set of N-channel MOS (NMOS) transistors connected in the mirror configuration.

4. The LC-VCO of claim 1, wherein the varactor bias voltage generation circuit comprises a plurality of transistors configured to mirror the PTAT current,
wherein the plurality of transistors comprise a first transistor, a current source transistor, one or more second transistors, and a cascode transistor,
wherein the first transistor is configured to generate a first bias voltage for the current source transistor, and
wherein the one or more second transistors are configured to generate a second bias voltage for the cascode transistor.

5. The LC-VCO of claim 1, wherein the varactor bias voltage generation circuit comprises a bias transistor configured to generate the varactor bias voltage, and
wherein a threshold voltage of the bias transistor is based on a complementary to absolute temperature (CTAT) voltage associated with the temperature condition.

6. The LC-VCO of claim 1, wherein the varactor circuit comprises a plurality of MOS capacitors, and wherein an effective gate overdrive voltage of the plurality of MOS capacitors is based on the varactor bias voltage.

7. The LC-VCO of claim 1, further comprising a first voltage regulator circuit and a second voltage regulator circuit connected in a cascade configuration.

8. The LC-VCO of claim 1, wherein the varactor circuit comprises at least one dummy poly structure between a source structure of a first transistor and a drain structure of a second transistor adjacent to the first transistor.

9. The LC-VCO of claim 1, wherein each of the current generation circuit and the varactor bias voltage generation circuit comprises one or more protection transistors.

10. The LC-VCO of claim 2, wherein the start-up circuit comprises one or more protection transistors.

11. The LC-VCO of claim 7, wherein at least one of the first voltage regulator circuit or the second voltage regulator circuit comprises at least one protection transistor.

12. The LC-VCO of claim 1, wherein the process condition corresponds to a deviation of a threshold voltage value of a transistor from a target threshold voltage value.

13. The LC-VCO of claim 6, wherein the effective gate overdrive voltage is based on a threshold voltage of the plurality of MOS capacitors, and the threshold voltage of the plurality of MOS capacitors is based on a CTAT voltage.

14. The LC-VCO of claim 1, wherein the LC tank comprises a negative transconductance circuit configured to compensate for a signal loss in the LC tank that is based on at least a contact resistance.

15. The LC-VCO of claim 14, wherein the negative transconductance circuit comprises a first NMOS transistor and a second NMOS transistor, and wherein the negative transconductance circuit comprises at least one dummy poly structure between the first NMOS transistor and the second NMOS transistor.

16. The LC-VCO of claim 1, wherein the current generation circuit comprises:
a NMOS protection transistor; and
a first PMOS transistor that has a source terminal connected to a power supply voltage, and
wherein a drain terminal of the NMOS protection transistor is connected to a drain terminal and a gate terminal of the first PMOS transistor.

17. A method of operating an inductor-capacitor (LC)-voltage controlled oscillator (VCO), comprising:
generating, using a current generation circuit of the LC-VCO, a proportional to absolute temperature (PTAT) current;
generating, using a varactor bias voltage generation circuit of the LC-VCO, a varactor bias voltage based on the PTAT current and on both a process condition and a temperature condition that are associated with the LC-VCO; and
adjusting, using a LC tank of the LC-VCO, an effective gate overdrive voltage of a capacitor of the LC tank based on the varactor bias voltage to compensate for a process variation of the process condition and a temperature variation of the temperature condition.

18. The method of claim 17, comprising:
restricting, using a start-up circuit of the LC-VCO, the current generation circuit from generating the PTAT current of a zero value.

19. The method of claim 17, comprising:
generating, using a first transistor of the varactor bias voltage generation circuit, a first bias voltage for a current source transistor of the varactor bias voltage generation circuit; and
generating, using one or more second transistors of the varactor bias voltage generation circuit, a second bias voltage for a cascode transistor of the varactor bias voltage generation circuit.

20. The method of claim 19, wherein generating the varactor bias voltage based on the PTAT current comprising:
generating, using a bias transistor of the varactor bias voltage generation circuit, the varactor bias voltage,
wherein the bias transistor, the cascode transistor, and the current source transistor are connected in series between a power supply and a ground level.
